(19) United States
(12) Patent Application Publication
(10) Pub. No.: US 2023/0422506 A1
(43) Pub. Date: Dec. 28, 2023

(54) LARGE GRAIN AND HALOGEN-FREE SILICON CELL CHANNEL FOR 3D NAND STRING

(71) Applicant: Intel Corporation, Santa Clara, CA (US)

(72) Inventor: Jessica S. Kachian, Half Moon Bay, CA (US)

(73) Assignee: Intel Corporation, Santa Clara, CA (US)

(21) Appl. No.: 18/367,319

(22) Filed: Sep. 12, 2023

(51) Int. Cl. H10B 43/27; H10B 41/27

(52) U.S. Cl. CPC H10B 43/27; H10B 41/27

(57) ABSTRACT

An example of an apparatus may include an array of linear cell channels and a string of NAND memory cells arranged along a cell channel of the array of linear cell channels, where a polysilicon cell channel layer comprises material with less than E17 halogen atoms per cubic centimeter, where a thickness of the polysilicon cell channel layer is less than or equal to 25 nanometers, and where an area-weighted grain height mean of the polysilicon cell channel layer is greater than 30 nanometers. Other examples are disclosed and claimed.

### BACKGROUND

A typical flash memory device may include a memory array that includes a large number of non-volatile memory cells arranged in row and column fashion. In recent years, vertical memory, such as three-dimensional (3D) memory, has been developed in various forms, such as NAND, cross-point, or the like. A 3D flash memory array may include a plurality of memory cells stacked over one another to form a vertical NAND string. In a floating gate flash cell, a conductive floating gate may be positioned between a control gate and a channel of a transistor. The individual memory cells of the vertical NAND string may be on different layers arranged around a body that extends outward from a substrate, with the conductive floating gate (charge storage region) located on a similar or same plane as the control gate, extending outward horizontally from the body.

There is an ongoing need for improved computational devices to enable ever increasing demand for modeling complex systems, providing reduced computation times, and other considerations. In some contexts, scaling features of ICs has been a driving force for such improvements. Other advancements have been made in materials, device structure, circuit layout, and so on. In particular, there is an ongoing desire to improve 3D NAND memory circuits that are utilized for, in, or otherwise support operation of ICs. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A and 1B are a block diagrams of a method, according to an example;

FIGS. 2A to 2C are side cross sectional views of an example of a memory device at different process stages;

FIGS. 3A to 3D are side cross sectional views of another example of a memory device at different process stages;

FIG. 4 is a side cross sectional view of an example of a floating gate NAND memory cell;

FIG. 5 is a side cross sectional view of another example of a floating gate NAND memory cell;

FIG. 6 is a block diagram of an apparatus, according to an example;

FIG. 7 is a block diagram of a memory device, according to an example; and

FIG. 8 is a block diagram of a system according to an example.

### DETAILED DESCRIPTION

One or more examples or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

References within this specification to “one example” or “an example” mean that a particular feature, structure, or characteristic described in connection with the example is included in at least one implementation encompassed within the present description. Therefore, the use of the phrase “one example” or “in an example” does not necessarily refer to the same example. In addition, the location or arrangement of individual elements within each disclosed example may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular examples, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, examples are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

While the following description sets forth various implementations that may be manifested in architectures such as system-on-a-chip (SoC) architectures for example, implementation of the techniques and/or arrangements described herein are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, etc., may implement the techniques and/or arrangements described herein. Further, while the following description may set forth numerous specific details such as logic implementations, types and interrelationships of system components, logic partitioning/integration choices, etc., claimed subject matter may be practiced without such specific details. In other instances, some material such as, for example, control structures and full software instruction sequences, may not be shown in detail in order not to obscure the material disclosed herein.

The material disclosed herein may be implemented in hardware, Field Programmable Gate Array (FPGA), firmware, driver, software, or any combination thereof. The material disclosed herein may also be implemented as instructions stored on a machine-readable medium, that may be read and executed by Moore Machine, Mealy Machine, and/or one or more processors. A machine-readable medium may include any medium and/or mechanism for storing or transmitting information in a form readable by a machine (e.g., a computing device). For example, a machine-readable medium may include read only memory (ROM); random access memory (RAM); Dynamic random-access memory (DRAM), magnetic disk storage media; optical storage media; non-volatile (NV) memory devices; qubit solid-state quantum memory, electrical, optical, acoustical or other forms of propagated signals (e.g., carrier waves, infrared signals, digital signals, etc.), and others.

References in the specification to “one implementation”, “an implementation”, “an example implementation”, etc., indicate that the implementation described may include a particular feature, structure, or characteristic, but every example may not necessarily include the particular feature, structure, or characteristic. Moreover, such phrases are not necessarily referring to the same implementation. Further, when a particular feature, structure, or characteristic is described in connection with an example, it is submitted that it is within the knowledge of one skilled in the art to implement such feature, structure, or characteristic in connection with other implementations whether or not explicitly described herein.

NV memory (NVM) may be a storage medium that does not require power to maintain the state of data stored by the medium. In one example, the memory device may include a three-dimensional (3D) NAND device. The memory device may refer to the die itself and/or to a packaged memory product. In particular examples, a memory component with non-volatile memory may comply with one or more standards promulgated by the JEDEC, or other suitable standard (the JEDEC standards cited herein are available at jedec.org).

Some 3D NAND silicon cell channel growth processes may include a preliminary seeding step and a main deposition step. The seeding step generally yields a small fraction of the total channel thickness and prepares the cell channel (e.g., surface roughness) for the next layer and/or provides structural (e.g., step coverage) properties. The main deposition step then grows the bulk of the final channel thickness. Thermal processes have been used for both the seeding and main deposition steps. In some processes, pseudo-atomic layer deposition (ALD) (e.g., involving a partially or fully chlorinated silane or disilane precursor) or disilane low pressure chemical vapor deposition (LPCVD) may be utilized for seeding, while silane LPCVD may be utilized for the main deposition component.

For 3D NAND string technology, without being limited to theory of operation, grain largeness may affect carrier mobility (e.g., string current down the stack) and grain boundary termination (e.g., also referred to as passivation) may affect cross-temperature (x-temp) loss. Larger grains (e.g., with targeted grain boundary passivation) may provide better node-over-node string current (e.g., while keeping x-temp loss neutral). A problem is that node-over-node increasing pillar aspect ratio and decreasing pillar critical dimension (CD) may limit the use of techniques such as Deposition Anneal Wet Etch (DAW), More Deposition More Cut (MDMC), etc., to achieve larger grains/decreasing density of grain boundaries (e.g., regions of relatively high defect/trap density).

Another approach to grain enlargement/grain boundary passivation may include targeted process chemistry (e.g., precursor/reactant selection based on available process window and desired reactivity outcome (e.g., towards resultant film properties)) for steps proximal to and including cell channel deposition. Some approaches to grain enlargement may utilize halogens such as chlorine in the chemistry. A problem is that such halogens may result in contamination (e.g., causing defects or other issues, particularly at an interface of the cell channel and the tunnel oxide) and/or may otherwise affect subsequent process steps. Another problem is that chlorine contamination at the tunnel oxide/cell channel interface shrinks cell channel grains (e.g., adversely affecting string current) and increases interface trap density. Another approach to grain enlargement may involve non-thermal post-deposition anneals (e.g., microwave, laser, etc.). A problem with non-thermal post-deposition anneals is additional cost and time (e.g., increased process window). A problem with some conventional halogen-free thermal processes is that such halogen-free thermal processes do not significantly enlarge grains.

Some examples may overcome one or more of the foregoing problems. Some examples may achieve larger grains (e.g., at matched channel thickness), and may not entail the use of halogen-containing chemistry. In some examples, the seeding step may be eliminated and channel grains may be substantially enlarged with suitable pre-channel deposition tunnel oxide surface preparation, main deposition LPCVD precursor selection for the channel deposition, and suitable post-channel deposition annealing processes.

Some examples provide technology for grain enlargement of a polysilicon cell channel in a high-aspect ratio pillar through targeted deposition precursor selection and improvement/optimization of pre-channel deposition tunnel oxide surface preparation, pre-channel deposition annealing, channel deposition, and post-channel deposition annealing processes. Advantageously, as compared to conventional chemistry and thermal-only processes at matched channel thickness, some examples may provide equivalent step coverage, larger grains, and potentially reduced defectivity due to the use of a halogen-free deposition precursor.

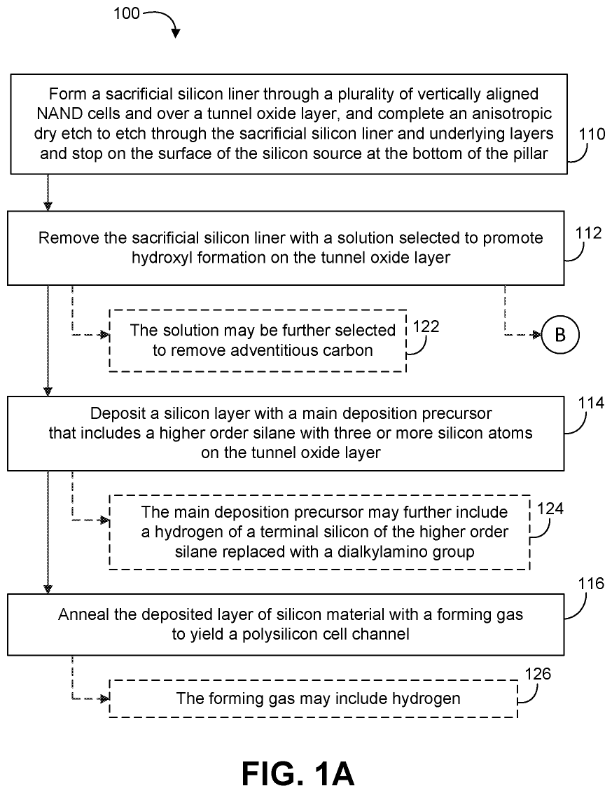

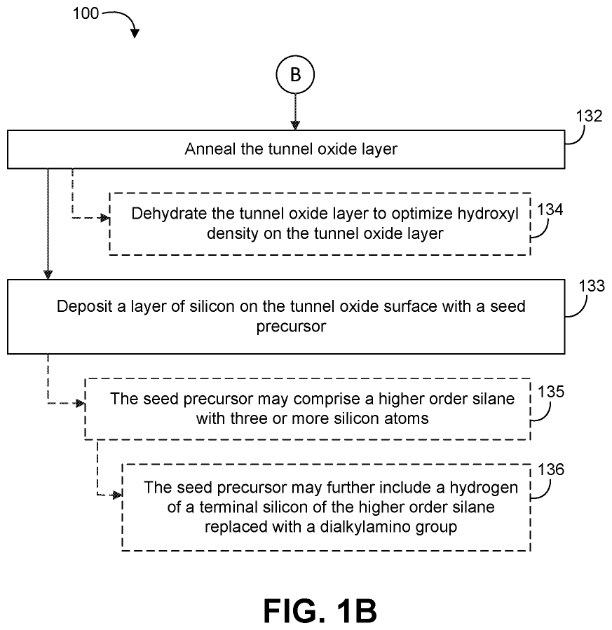

With reference to FIGS. 1A to 1B, an example of a method 100 to manufacture a memory device may include forming a sacrificial silicon liner through a plurality of vertically aligned NAND cells and over a tunnel oxide layer (e.g., to protect the tunnel oxide during the punch etch), and completing an anisotropic dry etch (also known as a “punch etch”) to etch through the sacrificial silicon liner and underlying layers and stop on the surface of the silicon source at the bottom of the pillar (leaving material on the pillar sidewall untouched) at box 110, removing the sacrificial silicon liner with a solution selected to promote hydroxyl formation on the tunnel oxide layer at box 112, depositing a silicon layer with a main deposition precursor that includes a higher order silane with three or more silicon atoms on the tunnel oxide layer at box 114, and annealing the deposited layer of silicon material with a forming gas at box 116 to yield a polysilicon cell channel (through crystallization of the aforementioned silicon material). In some examples, the solution may be further selected to remove adventitious carbon at box 122. In some examples, the main deposition precursor may further include a hydrogen of a terminal silicon of the higher order silane replaced with a dialkylamino group at box 124. In some examples, the forming gas may include hydrogen at box 126.

In some examples, the method 100 may further include (e.g., after removing the sacrificial silicon liner at box 112 and before main deposition via the main deposition precursor at box 114) annealing the tunnel oxide layer at box 132, and depositing a layer of silicon on the tunnel oxide surface with a seed precursor at box 133. In some examples, annealing the tunnel oxide layer at box 132 may further include dehydrating the tunnel oxide layer to optimize hydroxyl density on the tunnel oxide layer (for the seeding step) at box 134. In some examples, the seed precursor may comprise a higher order silane with three or more silicon atoms at box 135. In some examples, the seed precursor may further include a hydrogen of a terminal silicon of the higher order silane replaced with a dialkylamino group at box 136.

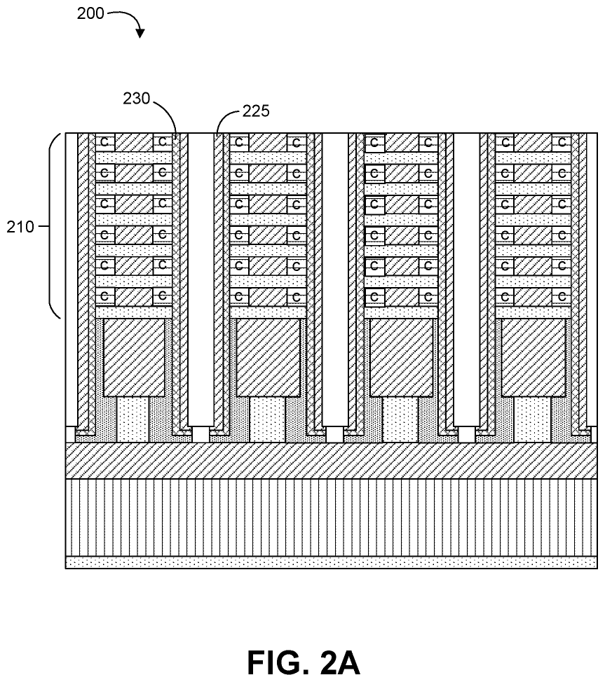

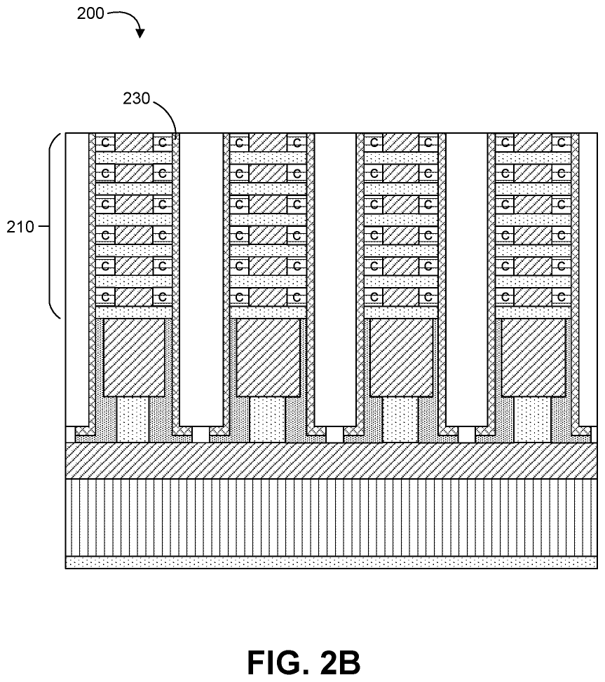

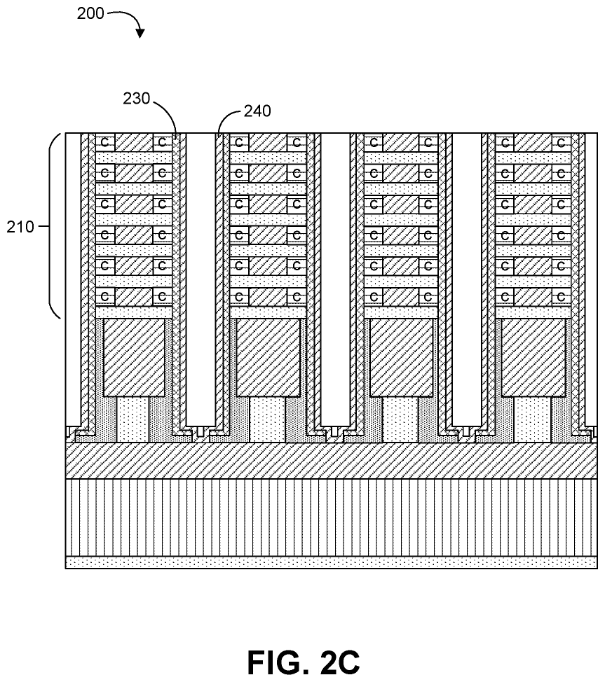

With reference to FIGS. 2A to 2C, an example of a memory device 200 includes an array of partially formed 3D NAND strings 210 with floating gate NAND memory cells (labeled as “c”) arranged along respective vertical cell tunnel oxide layers 230. Although only a few NAND memory cells are shown on each of the strings 210, those skilled in the art will appreciate that the strings 210 may include many more such cells along the length of the respective strings 210.

FIG. 2A shows a post-punch (anisotropic dry etch, see above) structure that includes a sacrificial silicon liner 225 conformally deposited along the tunnel oxide layer 230 along which the NAND memory cells are vertically/axially aligned (for each pillar); note that in FIG. 2A, neither the sacrificial liner (225) nor the tunnel oxide (230) is present near the pillar bottoms, as the punch has removed those materials from the specified location (along with additional material at that location to enable exposure of the surface of the silicon source). Any suitable process technology may be utilized to form the 3D NAND strings 210 with the sacrificial liner 225. In accordance with some examples, the sacrificial liner 225 is removed with a halogen-free chemical solution selected to prepare the tunnel oxide layer 230 to promote larger cell channel grains in subsequent processing (e.g., an improvement or optimization of a pre-channel deposition tunnel oxide surface preparation).

FIG. 2B shows the memory device 200 post-sacrificial liner removal (PLR). The tunnel oxide layer 230 is exposed for further processing. After PLR, in accordance with some examples, a main deposition process may form a silicon layer 240 constituting the vertical cell channel. The material/precursor for the main deposition process is selected to promote larger grains.

FIG. 2C shows the memory device 200 after the main deposition, which forms the vertical silicon cell channel layer 240. After the main deposition, a post-channel deposition annealing (PDA) process may promote grain growth/enlargement in the vertical silicon cell channel layer 240 and result in larger grains for the vertical silicon cell channel 240 such that it is definitively polycrystalline. Any suitable further processes (e.g., direct hollow channel (DHC) poly reflow, etc.) may follow the PDA process to complete the manufacture of the memory device 200 into an IC that may be incorporated in an electronic device.

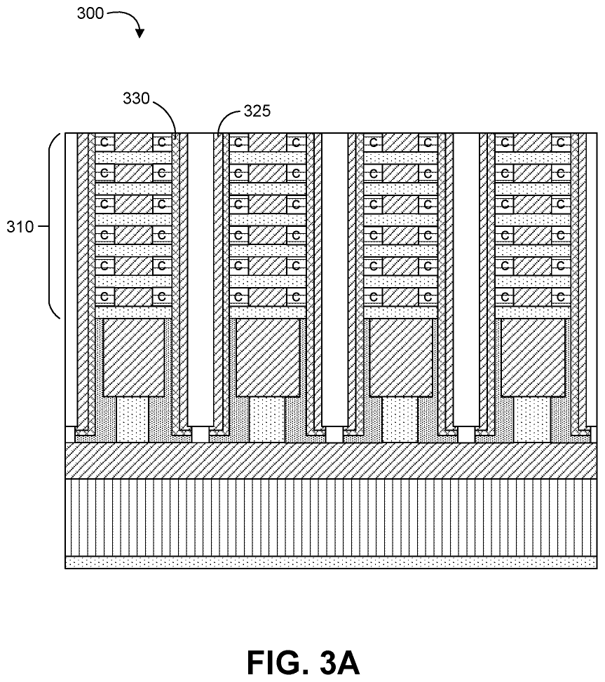

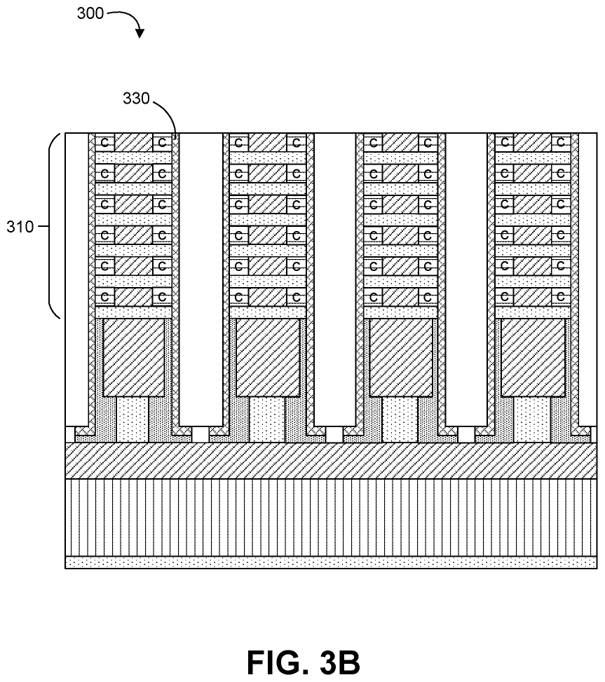

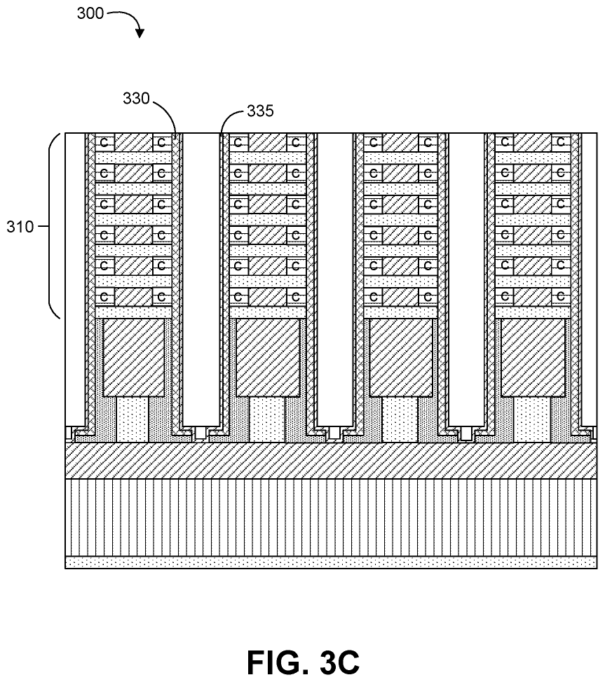

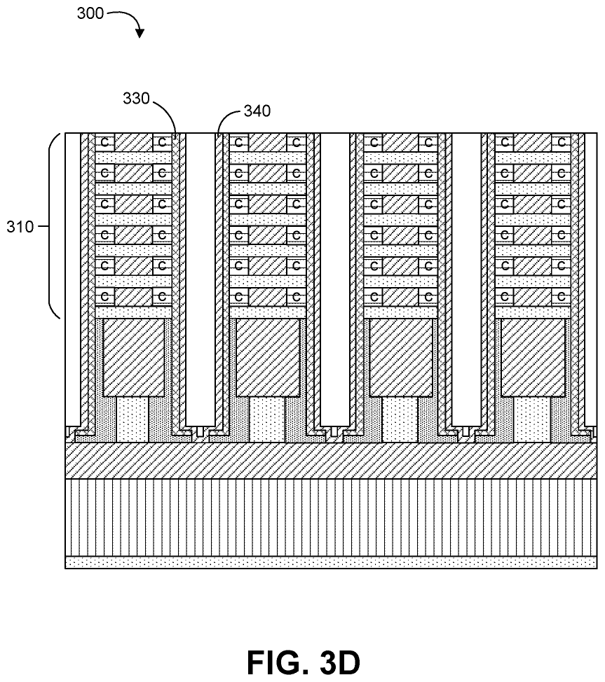

With reference to FIGS. 3A to 3D, an example of a memory device 300 includes an array of partially formed 3D NAND strings 310 with floating gate NAND memory cells (labeled as “c”) arranged along respective vertical cell tunnel oxide layers 330. Although only a few NAND memory cells are shown on each of the strings 310, those skilled in the art will appreciate that the strings 310 may include many more such cells along the length of the respective strings 310.

FIG. 3A shows a post-punch (anisotropic dry etch, see above) structure that includes a sacrificial silicon liner 325 conformally deposited along the tunnel oxide layer 330 along which the NAND memory cells are vertically/axially aligned (for each pillar); note that in FIG. 3A, neither the sacrificial liner (325) nor the tunnel oxide (330) is present near the pillar bottoms, as the punch has removed those materials from the specified location (along with additional material at that location to enable exposure of the surface of the silicon source). Any suitable process technology may be utilized to form the 3D NAND strings 310 with the sacrificial liner 325. In accordance with some examples, the sacrificial liner 325 is removed with a halogen-free chemical solution selected to prepare the tunnel oxide layer 330 to promote larger cell channel grains in subsequent processing (e.g., an improvement or optimization of a pre-channel deposition tunnel oxide surface preparation).

FIG. 3B shows the memory device 300 post-PLR. The tunnel oxide layer 330 is exposed for further processing. After PLR, a halogen-free pre-DA process may further prepare the tunnel oxide layer 330 to promote larger cell channel grains in subsequent processing. After the pre-DA, in accordance with some examples, a seed deposition process may form a thin silicon layer 335 constituting part of the vertical cell channel. The material for the seed deposition process is selected to promote larger cell channel grains.

FIG. 3C shows the memory device after the seed deposition process that forms the thin silicon layer 335 constituting part of the vertical cell channel. After seed deposition, a main deposition process may complete the formation of the vertical silicon cell channel 340. Note that silicon layer 335 is part of layer 340 (see FIG. 3D) when both seed and main deposition processes are used, where main deposition is always used. The material/precursor for the main deposition process is selected to promote larger cell channel grains.

FIG. 3D shows the memory device 300 after the main deposition, which is the sole source of silicon for the vertical silicon cell channel layer 340 when no seed deposition is used and which completes formation (through silicon deposition) of the vertical silicon cell channel when a preceding seeding deposition is used. After the main deposition, a PDA process may promote grain growth/enlargement in the vertical silicon cell channel layer 340 and result in larger grains for the vertical silicon cell channel layer 340. Any suitable further processes (e.g., DHC poly reflow, etc.) may follow the PDA process to complete the manufacture of the memory device 300 into an IC that may be incorporated in an electronic device.

### Example Processes

Those skilled in the art will appreciate that various solutions, chemistries, precursors, and/or other elements may be utilized for various of the example grain enlargement process steps based on a targeted reaction(s) during the given step, intended transformational material effect of each element, and on various cell channel criteria. The examples described herein should be considered as illustrative only and not limiting.

### Examples for Pre-Channel Deposition Surface Preparation

In some examples, a wet etch process may be utilized to prepare the tunnel oxide surface prior to either seed deposition or main deposition. Preparation of the tunnel oxide surface may utilize an aqueous preclean chemistry selected to optimize, maximize, or otherwise promote increased hydroxyl density on the tunnel oxide (e.g., thermal SiO₂) surface. In one example, with or without pre-DA and seeding, an example process may include utilizing suitable aqueous solutions to strip the sacrificial liner material (e.g., hydrofluoric acid (HF) to remove the native oxide from the sacrificial liner followed by tetra methyl ammonium hydroxide (TMAH) to remove the sacrificial liner itself).

### Examples for Channel Main Deposition

In some examples, a LPCVD process may be utilized for the channel main deposition. For example, a silicon LPCVD process may be improved or optimized (e.g., precursor partial pressure, deposition temperature, process pressure, etc.) for main deposition precursor materials such as higher order silanes that include three or more silicon atoms (e.g., trisilane, trisilane with a hydrogen of a terminal silicon of the trisilane replaced with a dialkylamino group, etc.). In one example, with or without pre-DA and seeding, the main deposition process may include trisilane plus a PH₃ source plus nitrogen. Without being limited to theory of operation, trisilane may provide additional reaction pathways (e.g., relative to disilane or silane). For example, trisilane may provide controlled access (e.g., with deposition temperature) to targeted reaction pathways with the hydroxyl-terminated tunnel oxide surface. Combining the foregoing with trisilane thermal pyrolysis pathways that produce an ideal gas mix (e.g., of SiH₄ and Si₂H₆) for main deposition may leverage the deposited Si step coverage, surface roughness, and grain enlargement advantages of its constituents.

### Examples for Post-Channel Deposition Annealing

In some examples, a process for post-channel deposition annealing (PDA) may include hydrogen in a forming gas. Various anneal times, temperatures, and anneal environment combinations may be utilized with the aim of grain boundary passivation (e.g., with hydrogen in the forming gas) and grain enlargement. In one example, the PDA may utilize a forming gas of nitrogen and hydrogen (e.g., H₂) (e.g., with an air break between the main deposition and the PDA) to hydrogen passivate dangling bonds, and/or to promote high-temp recombinative hydrogen desorption/grain coalescence.

Any suitable techniques may be utilized to measure grain largeness. For example, Annular dark-field transmission electron microscopy (ADF-TEM) may be utilized to assess grain largeness (e.g., as a function of processes, etc.). ADF-TEM may be utilized to provide two-dimensional (2D) images of the grains. In one example model, the shape of the 2D grain image may be defined as an ellipse (e.g., with two dimensions=a and b major and minor axes, respectively), where a grain height (GH) may correspond to a length of the major axis. With the shape of the 2D grain image modelled as an ellipse, computational time may be reasonable and the model may be complex enough (e.g., with two dimensions to describe the shape of the 2D grain image) to allow for decoupling channel thickness and grain largeness. Employing the ellipse model may entail calculating projections of the major and minor ellipse axes onto the pillar sidewall/axial dimension (to give grain height) and pillar radial dimension (for comparison to channel thickness). In employing a GH-based model, the grain boundary density in the dimension along which string current is conducted (axial) may be estimated, for a given string/cell channel of a given thickness, and the cell channel resistance/string current may accordingly also be estimated.

An example useful measurement may involve an area weighted (AW) calculation and a mean (M) calculation. The aforementioned area-weighted mean corresponds to an arithmetic mean that employs area weighting of the variable of interest (e.g., GH in an area-weighted grain height mean (AWGHM)) to calculate the mean of that variable. For the GH model, the area is the area of the ellipse defining the 2D grain image. Area weighting may be preferred (e.g., over no weighting) because area weighting may emphasize large grains (e.g., of which most of the channel volume is comprised), thus providing for a better correlation of grain largeness with string current.

In some examples, with pre-DA and seeding, an AWGHM measured for the cell channel at the top of the pillar (e.g., at a point along a topmost 20% of the height of the pillar) may be in excess of 61 nm for a cell channel thickness of 17-20 nm and in excess of 16 nm for a cell channel thickness of 7 nm, an AWGHM measured at the middle of the pillar (e.g., at a point within plus or minus 10% of the center point of a lengthwise/axial axis of the pillar) may be in excess of 79 nm for a cell channel thickness of 20 nm, in excess of 68 nm for a cell channel thickness of 17 nm, and in excess of 24 nm for a cell channel thickness of 7 nm, and an AWGHM measured at the bottom of the pillar (e.g., at a point along a bottommost 20% of the height of the pillar) may be in excess of 65 nm for a cell channel thickness of 20 nm, in excess of 41 nm for a cell channel thickness of 16 nm, and in excess of 37 nm for a cell channel thickness of 7 nm. In some examples, without pre-DA and seeding, an AWGHM measured at the top of the pillar may be in excess of 63 nm for a cell channel thickness of 20 nm, in excess of 59 nm for a cell channel thickness of 16 nm, and in excess of 20 nm for a cell channel thickness of 6 nm, an AWGHM measured at the middle of the pillar may be in excess of 71 nm for a cell channel thickness of 20 nm and in excess of 39 nm for a cell channel thickness of 16 nm, and an AWGHM measured at the bottom of the pillar may be in excess of 38 nm for a cell channel thickness of 20 nm and in excess of 62 nm for a cell channel thickness of 15 nm.

Advantageously, some examples may demonstrate a grain enlargement relative to other halogen-free techniques (e.g., at matched channel thickness) with commensurate positive impacts to string current, without impacts to step coverage, and potentially with improvement in x-temp loss (e.g., due to the absence of halogens in the deposition process and to the inclusion of forming gas in the post-deposition annealing step).

### Examples for Optional Pre-Channel Deposition Anneal

As noted hereinabove, some examples may include a pre-DA and seeding process that may provide further improvements in grain enlargement, particularly at a bottom portion of the pillar. For different applications, a user can weigh raw processing time and material costs against grain largeness benefits of the pre-DA and seeding processes to determine whether or not to include the pre-DA and seeding processes for a target memory device.

In some examples, a pre-DA process may utilize various anneal time/temperature combinations with the aim of dehydrating the tunnel oxide surface produced in the preceding wet surface preparation process to yield a surface hydroxyl density optimized for the first growth step that follows the pre-DA. In one example, the pre-DA process may utilize nitrogen to dehydrate the tunnel oxide surface to yield targeted nucleation site density by targeting surface hydroxyl density that favors seed precursor reaction with one surface hydroxyl site and across the precursor Si—N bond.

### Examples for Optional Channel Seed Deposition

In some examples, a channel seed deposition may utilize a LPCVD process and/or a dissociative chemisorption process. In some examples, a silicon LPCVD process and/or a dissociative chemisorption process utilizing Si-containing precursor(s) may be improved or optimized (e.g., precursor partial pressure, deposition temperature, process pressure, etc.) for seed deposition precursor materials such as higher order silanes that include three or more silicon atoms (e.g., trisilane, trisilane with a hydrogen of a terminal silicon of the trisilane replaced with a dialkylamino group, etc.). Without being limited to theory of operation, the indicated seed precursors may provide controlled access (e.g., with deposition temperature) to targeted reaction pathways with the hydroxyl-terminated tunnel oxide surface.

For the trisilane with a hydrogen of a terminal silicon replaced with a dialkylamino group, the seed precursor material may selectively adsorb on the tunnel oxide surface across the Si—N bond of the seed precursor (e.g., with an advantage in controlling nucleation site density). In one example, the process may include the seed precursor plus nitrogen to provide the desired seed precursor reaction with one tunnel oxide surface hydroxyl site and across the Si—N bond.

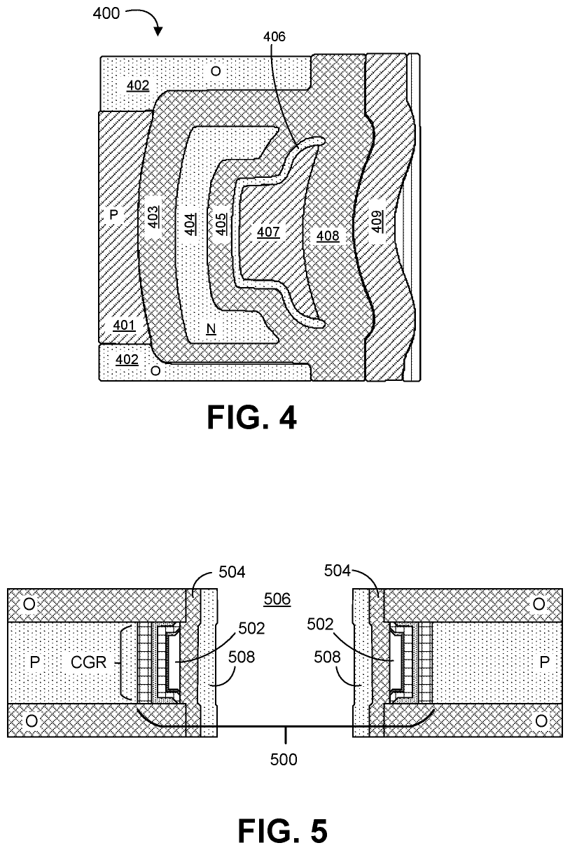

With reference to FIG. 4, an example floating gate NAND memory cell 400 includes a halogen-free silicon cell channel with grains of considerable largeness (e.g., high AWGHM), as described herein, for a 3D NAND string. For examples, the NAND memory cell 400 may be manufactured using one or more aspects of the method 100 (FIG. 1) and/or the processes described in connection with FIGS. 2A-C and FIGS. 3A-D. The cross-section shown in FIG. 4 is illustrative of one side of an example NAND cell shown in FIG. 2C and FIG. 3D. As shown in FIG. 4, an embodiment of the floating gate NAND memory cell 400 may include a polysilicon WL 401, silicon oxide layers 402, high-quality silicon oxide layers 403, 405, and 408, silicon nitride layers 404 and 406, and polysilicon layers 407 and 409, arranged as illustrated as part of the cell stack. In general, the manufacture and construction of the memory cell 400 may be a floating gate NAND memory cell with alternating layers of oxide and polysilicon (e.g., an OPOP stack) and with an outermost layer 403 of thermal silicon oxide extending from the control gate to the floating gate to provide an etch stop layer (ESL) for a silicon nitride layer 404 of the memory cell 400. For example, the layers 403, 404, 405, and 406 may be inter-gate dielectric (IGD) layers, the layer 407 may be a polysilicon floating gate, the layer 408 may be a tunnel oxide, and the layer 409 may be a polysilicon channel.

A concentration may be expressed as the number ten (10) raised to an exponent (E) that corresponds to the order of magnitude for the number of atoms per cubic centimeter in the material (e.g., E20 represents 10 raised to the 20 power). In some examples of the memory cell 400, the layer 409 may comprise a material with less than E17 halogen atoms per cubic centimeter (e.g., less than E16 in some examples (e.g., undetectable where the secondary ion mass spectrometer (SIMS) concentration detection limit is 1E16, and there is no source of halogen in the described processes—with or without pre-DA and seeding)), and an AWGHM of the layer 409, when generated without pre-DA and seeding, may be greater than 28 nanometers for a layer 409 thickness of 20 nanometers and greater than 29 nanometers for a 409 layer thickness of 16 nanometers (e.g., greater than 47 nanometers for a layer 409 thickness of 20 nanometers and greater than 43 nanometers for a layer 409 thickness of 16 nanometers in some examples; greater than 61 nanometers for a layer 409 thickness of 20 nanometers, greater than 52 nanometers for a layer 409 thickness of 15 nanometers in some examples, and greater than 10 nanometers for a layer 409 thickness of 6 nanometers in some examples).

In some examples of the memory cell 400, the layer 409 may comprise a material with less than E17 halogen atoms per cubic centimeter (e.g., less than E16 in some examples), and an AWGHM of the layer 409, when generated with pre-DA and seeding, may be greater than 51 nanometers for a layer 409 thickness of 20 nanometers, greater than 31 nanometers for a 409 layer thickness of 16 nanometers, and greater than 6 nm for a 409 layer thickness of 7 nanometers (e.g., greater than 58 nanometers for a layer 409 thickness of 20 nanometers, greater than 47 nanometers for a layer 409 thickness of 17 nanometers, and greater than 16 nanometers for a layer 409 thickness of 7 nanometers in some examples; greater than 69 nanometers for a layer 409 thickness of 20 nanometers, greater than 58 nanometers for a layer 409 thickness of 17 nanometers, and greater than 27 nanometers for a layer 409 thickness of 7 nanometers in some examples). In some examples, the layer 409 may be substantially chlorine-free at an interface between the layer 409 and the layer 408 (e.g., the tunnel oxide layer).

With reference to FIG. 5, an example floating gate NAND memory cell 500 includes a large-grain and halogen-free silicon cell channel, as described herein, for a 3D NAND string. For examples, the NAND memory cell 500 may be manufactured using one or more aspects of the method 100 (FIG. 1) and/or the processes described in connection with FIGS. 2A-C and FIGS. 3A-D. The cross-section shown in FIG. 5 is illustrative of opposed sides of an example NAND cell shown in FIG. 2C and FIG. 3D (e.g., a both sides of the channels 240, 340). As shown in FIG. 5, an embodiment of the floating gate NAND memory cell 500 may include alternating layers of oxide and polysilicon (e.g., an OPOP stack) with a trap base 502 and other suitable materials forming the memory cell 500 within a control gate recess (CGR) in the poly layers of the OPOP stack. A tunnel oxide layer 504 covers the trap base 502 and extends outside the pocket of the CGR. For example, as shown in FIG. 5, the tunnel oxide layer 504 may be deposited in a pillar 506 to cover the trap base 502. As further shown in FIG. 5, a polysilicon cell channel layer 508 may be formed in the pillar 506 over the tunnel oxide layer 504.

In some examples of the memory cell 500, the layer 508 may comprise a material with less than E17 halogen atoms per cubic centimeter (e.g., less than E16 in some examples), and an AWGHM of the layer 508, when generated without pre-DA and seeding, may be greater than 28 nanometers for a layer 508 thickness of 20 nanometers and greater than 29 nanometers for a 508 layer thickness of 16 nanometers (e.g., greater than 47 nanometers for a layer 508 thickness of 20 nanometers and greater than 43 nanometers for a layer 508 thickness of 16 nanometers in some examples; greater than 61 nanometers for a layer 508 thickness of 20 nanometers, greater than 52 nanometers for a layer 508 thickness of 15 nanometers, and greater than 10 nanometers for a layer 508 thickness of 6 nanometers in some examples). In some examples of the memory cell 500, the layer 508 may comprise a material with less than E17 halogen atoms per cubic centimeter (e.g., less than E16 in some examples), and an AWGHM of the layer 508, when generated with pre-DA and seeding, may be greater than 51 nanometers for a layer 508 thickness of 20 nanometers, greater than 31 nanometers for a 508 layer thickness of 16 nanometers, and greater than 6 nm for a 508 layer thickness of 7 nanometers (e.g., greater than 58 nanometers for a layer 508 thickness of 20 nanometers, greater than 47 nanometers for a layer 508 thickness of 17 nanometers, and greater than 16 nanometers for a layer 508 thickness of 7 nanometers in some examples; greater than 69 nanometers for a layer 508 thickness of 20 nanometers, greater than 58 nanometers for a layer 508 thickness of 17 nanometers, and greater than 27 nanometers for a layer 508 thickness of 7 nanometers in some examples). In some examples, the layer 508 may be substantially chlorine-free at an interface between the layer 508 and the layer 504 (e.g., the tunnel oxide layer).

Given the benefit of the present specification and drawings, those skilled in the art will appreciate that numerous other memory cell configurations and types (e.g., charge trap flash, etc.) may beneficially utilize one or more aspects of the various examples described herein.

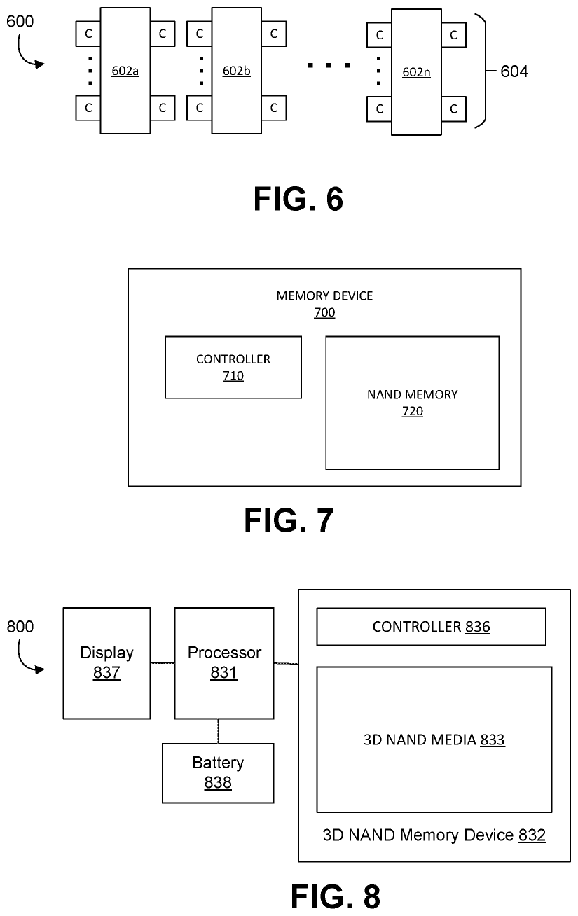

FIG. 6 shows an example of an apparatus 600 that includes an array of linear cell channels 602a through 602n (collectively 602), and a string 604 of NAND memory cells (labelled “C”) arranged along a cell channel 602a of the array of linear cell channels 602, where the cell channel 602a may comprise a material with less than E17 halogen atoms per cubic centimeter, and where an AWGHM of the channel layer, when generated without pre-DA and seeding, may be greater than 28 nanometers for a cell channel thickness of 20 nanometers and greater than 29 nanometers for a cell channel thickness of 16 nanometers (e.g., greater than 47 nanometers for a cell channel thickness of 20 nanometers and greater than 43 nanometers for a cell channel thickness of 16 nanometers in some examples; greater than 61 nanometers for a cell channel thickness of 20 nanometers, greater than 52 nanometers for a cell channel thickness of 15 nanometers, and greater than 10 nanometers for a cell channel thickness of 6 nanometers in some examples).

In some examples, the cell channel 602a may comprise a material with less than E17 halogen atoms per cubic centimeter, and where an AWGHM of the channel layer, when generated with pre-DA and seeding, may be greater than 51 nanometers for a cell channel thickness of 20 nanometers, greater than 31 nanometers for a cell channel thickness of 16 nanometers, and greater than 6 nm for a cell channel thickness of 7 nanometers (e.g., greater than 58 nanometers for a cell channel thickness of 20 nanometers, greater than 47 nanometers for a cell channel thickness of 17 nanometers, and greater than 16 nanometers for a cell channel thickness of 7 nanometers in some examples; greater than 69 nanometers for a cell channel thickness of 20 nanometers, greater than 58 nanometers for a cell channel thickness of 17 nanometers, and greater than 27 nanometers for a cell channel thickness of 7 nanometers in some examples). In some examples, the channel material may comprise less than E16 halogen atoms per cubic centimeter. In some examples, the channel material may be substantially halogen-free. In some examples, the apparatus 600 may further include a tunnel oxide layer adjacent to the cell channel layer 602a, where the cell channel layer is substantially chlorine-free at an interface between the cell channel layer and the tunnel oxide layer.

FIG. 7 shows an example of a memory device 700 that includes a controller 710 and NAND memory 720 coupled to the controller 710. In some examples, the NAND memory 720 may include an array of vertical NAND strings, where a vertical cell channel of the array includes a plurality of NAND cells arranged along the vertical cell channel with a tunnel oxide material disposed between the plurality of NAND cells and the vertical cell channel, and where the vertical cell channel material may comprise less than E17 halogen atoms per cubic centimeter, and where an AWGHM of the polysilicon vertical cell channel, when generated without pre-DA and seeding, may be greater than 28 nanometers for a cell channel thickness of nanometers and greater than 29 nanometers for a cell channel thickness of 16 nanometers (e.g., greater than 47 nanometers for a cell channel thickness of 20 nanometers and greater than 43 nanometers for a cell channel thickness of 16 nanometers in some examples; greater than 61 nanometers for a cell channel thickness of 20 nanometers, greater than 52 nanometers for a cell channel thickness of 15 nanometers, and greater than 10 nanometers for a cell channel thickness of 6 nanometers in some examples).

In some examples, the vertical cell channel material may comprise less than E17 halogen atoms per cubic centimeter, and an AWGHM of the polysilicon vertical cell channel, when generated with pre-DA and seeding, may be greater than 51 nanometers for a cell channel thickness of 20 nanometers, greater than 31 nanometers for a cell channel thickness of 16 nanometers, and greater than 6 nm for a cell channel thickness of 7 nanometers (e.g., greater than 58 nanometers for a cell channel thickness of 20 nanometers, greater than 47 nanometers for a cell channel thickness of 17 nanometers, and greater than 16 nanometers for a cell channel thickness of 7 nanometers in some examples; greater than 69 nanometers for a cell channel thickness of 20 nanometers, greater than 58 nanometers for a cell channel thickness of 17 nanometers, and greater than 27 nanometers for a cell channel thickness of 7 nanometers in some examples). In some examples, the polysilicon vertical cell channel may comprise less than E16 halogen atoms per cubic centimeter. In some examples, the polysilicon vertical cell channel may be substantially halogen-free. In some examples, the halogen comprises chlorine and the polysilicon vertical cell channel may be substantially chlorine-free at an interface between the polysilicon vertical cell channel layer and the tunnel oxide layer. For example, the NAND memory 720 may comprise 3D NAND memory.

With reference to FIG. 8, an example of a system 800 may include a processor 831 and a 3D NAND memory device 832 coupled to the processor. In some examples, the 3D NAND memory device 832 may be similarly configured as the various examples described herein (e.g., the memory device 200, the memory device 300, the apparatus 600, the memory device 700, etc.). In some examples, the 3D NAND memory device 832 may include 3D NAND media 833 comprising an array of vertical NAND strings, where a vertical cell channel of the array includes a plurality of NAND cells arranged along the vertical cell channel with a dielectric material disposed between the plurality of NAND cells and the vertical cell channel, and where the polysilicon vertical cell channel may comprise less than E17 halogen atoms per cubic centimeter, and where an AWGHM of the vertical cell channel, when generated without pre-DA and seeding, may be greater than 28 nanometers for a cell channel thickness of 20 nanometers and greater than 29 nanometers for a cell channel thickness of 16 nanometers (e.g., greater than 47 nanometers for a cell channel thickness of 20 nanometers and greater than 43 nanometers for a cell channel thickness of 16 nanometers in some examples; greater than 61 nanometers for a cell channel thickness of 20 nanometers, greater than 52 nanometers for a cell channel thickness of 15 nanometers, and greater than 10 nanometers for a cell channel thickness of 6 nanometers in some examples).

In some examples, the polysilicon vertical cell channel may comprise less than E17 halogen atoms per cubic centimeter, and an AWGHM of the vertical cell channel, when generated with pre-DA and seeding, may be greater than 51 nanometers for a cell channel thickness of 20 nanometers, greater than 31 nanometers for a cell channel thickness of 16 nanometers, and greater than 6 nm for a cell channel thickness of 7 nanometers (e.g., greater than 58 nanometers for a cell channel thickness of 20 nanometers, greater than 47 nanometers for a cell channel thickness of 17 nanometers, and greater than 16 nanometers for a cell channel thickness of 7 nanometers in some examples; greater than 69 nanometers for a cell channel thickness of 20 nanometers, greater than 58 nanometers for a cell channel thickness of 17 nanometers, and greater than 27 nanometers for a cell channel thickness of 7 nanometers in some examples).

In some examples, the 3D NAND memory device 832 may further include a controller 836. In some examples, the polysilicon vertical cell channel may comprise less than E16 halogen atoms per cubic centimeter. In some examples, the polysilicon vertical cell channel may be substantially halogen-free. In some examples, the halogen comprises chlorine and wherein the polysilicon vertical cell channel is substantially chlorine-free at an interface between the vertical cell channel and the dielectric material. In some examples, the system 800 may further include one or more of a display 837, a battery 838, and a peripheral device (not shown) coupled to the processor 831.

The processor 831 may include or be communicatively coupled to one or more of a general purpose controller, a special purpose controller, a memory controller, a storage controller, a micro-controller, an execution unit, etc. In some examples, the NAND media 833, the controller 836, and/or other system memory may be located in, or co-located with, various components, including the processor 831 (e.g., on a same die or package substrate). For example, the processor 831 may include a memory controller and be implemented as a connected memory device such as a memory module, a non-volatile dual-inline memory module (NVDIMM), a solid-state drive (SSD), a memory node, etc.

Examples of a suitable processor and each of the above NAND media 833, controller 836, and other system components may be implemented in hardware, software, or any suitable combination thereof. For example, hardware implementations may include configurable logic, fixed-functionality logic, or any combination thereof. Examples of configurable logic include suitably configured programmable logic arrays (PLAs), FPGAs, complex programmable logic devices (CPLDs), and general purpose microprocessors. Examples of fixed-functionality logic include suitably configured application specific integrated circuits (ASICs), combinational logic circuits, and sequential logic circuits. The configurable or fixed-functionality logic may be implemented with complementary metal oxide semiconductor (CMOS) logic circuits, transistor-transistor logic (TTL) logic circuits, or other circuits.

For example, the controller 836 may be implemented with circuitry on a semiconductor apparatus, that may include one or more substrates, with the circuitry coupled to the one or more substrates. In some examples, the circuitry may be at least partly implemented in one or more of configurable logic and fixed-functionality hardware logic on semiconductor substrate(s) (e.g., silicon, sapphire, gallium-arsenide, etc.). For example, the circuitry may include a transistor array and/or other integrated circuit components coupled to the substrate(s) with transistor channel regions that are positioned within the substrate(s). The interface between the circuitry and the substrate(s) may not be an abrupt junction. The circuitry may also be considered to include an epitaxial layer that is grown on an initial wafer of the substrate(s).

Alternatively, or additionally, all or portions of these components may be implemented in one or more modules as a set of logic instructions stored in a machine- or computer-readable storage medium such as RAM, ROM, programmable ROM (PROM), firmware, etc., to be executed by a processor or computing device. For example, computer program code to carry out the operations of the components may be written in any combination of one or more operating system (OS) applicable/appropriate programming languages, including an object-oriented programming language such as PYTHON, PERL, JAVA, SMALLTALK, C++, C #, VHDL, Verilog, System C or the like and conventional procedural programming languages, such as the “C” programming language or similar programming languages. For example, the NAND media, other persistent storage media, or other system memory may store a set of instructions (e.g., that may be firmware instructions) that when executed by the processor 831 cause the system 800 to implement one or more components, features, or aspects of the system.

An example NAND flash memory array may include multiple NAND memory cells arranged in columns, such as 3D NAND series strings. In one example, the memory cell includes a transistor with a replacement gate. A cell with a replacement gate typically has a low resistance gate (e.g., a tungsten gate) and a charge trap layer between the gate and the channel where charge is trapped or stored to represent one or more bit values. In another example, a memory cell can include a transistor with a floating gate (e.g., a high resistance poly gate) that stores charge indicative of one or more bit values. Other architectures are also possible. In the series strings, drain regions of cells are (with the exception of the top cell) coupled to a source region of another cell.

The NAND flash memory array also includes wordlines (WLs). The WLs can span across multiple series strings (e.g., a WL may be coupled to one memory cell of each series string) and are connected to the control gates of each memory cell of a row of the array and used to bias the control gates of the memory cells in the row. The bitlines (BLs) are each coupled to a series string by a drain select gate and sensing circuitry that detects the state of each cell by sensing voltage or current on a particular BL.

Multiple series strings of the memory cells are coupled to a source line by a source select gate and to an individual BL by a drain select gate. The source select gates are controlled by a source select gate control line and the drain select gates are controlled by a drain select gate control line.

In some examples, each memory cell can be programmed according to various encoding schemes such as SLC (single level cell), MLC (multi-level cell) TLC (triple level cell), QLC (quad level cell), or other encoding scheme. Each cell's threshold voltage (Vt) is indicative of the data that is stored in the cell.

In one example, a cell state that is set to store multiple bits may form a part of multiple different pages, with each bit of the cell corresponding to a distinct page. For example, for a cell that is to enter a state to store two (2) bits (e.g., using an MLC encoding scheme), one bit may correspond to an Upper Page (UP) and the other bit may correspond to a Lower Page (LP). For a cell that is to enter a state to store three (3) bits (e.g., using a TLC encoding scheme), one bit may correspond to an LP, one bit may correspond to a UP, and the other bit may correspond to an Extra Page (XP). For a cell that is to store four (4) bits (e.g., using a QLC encoding scheme), one bit may correspond to an LP, another bit may correspond to a UP, another bit may correspond to an XP, and the final bit may correspond to a Top Page (TP). Each page (e.g., LP, UP, XP, or TP) may include an aggregation of corresponding bits stored by a plurality of different cells of a WL.

A programming sequence for a group of cells may include programming of all of the intended pages into the group of cells. A programming sequence may include one or more programming passes. A programming pass (that may include one or more programming loops) may program one or more pages. A programming pass may include the application of one or more effective program voltages to cells to be programmed followed by the application of one or more verify voltages to these cells in order to determine which cells have finished programming (subsequent programming passes generally will not apply an effective program voltage and/or a verify voltage to the cells that have finished programming). The application of an effective program voltage to a cell may include changing the voltage difference between a control gate and a channel of the cell in order to change the threshold voltage of the cell. Accordingly, a voltage of a WL (coupled to the control gate of the target cell) and/or a channel of the cell may be set in order to effectuate application of an effective program voltage. As a program voltage is commonly used to refer to a voltage applied to a WL, the effective program voltage can be the voltage difference between a control gate and channel of a cell (that in instances where the channel is held at 0 V can be synonymous with a program voltage).

In one example, a controller for a non-volatile memory device includes input/output (I/O) interface circuitry to receive requests from a processor to access a non-volatile memory die, and control logic to generate commands in response to the requests from the processor, each of the commands to access one of multiple planes of the 3D memory die, queue the commands in separate queues for each of the planes based on a target plane of each of the commands, issue the commands to their target planes independent of other planes' status, and track completion status of the commands independently for each plane.

In one example, an article of manufacture including a computer readable storage medium having content stored thereon that when accessed causes processing circuitry to execute operations to perform a method described herein. For example, a method can include issuing, from a controller, a command to a 3D NAND die, the die including multiple planes, the command to target a first plane of the die, issuing a second command to the 3D NAND die to target a second plane while the first plane is busy, and tracking completion of both the first and second commands by polling status of the first plane and the second plane. In one example, a method includes receiving, at a 3D NAND die, a first command from a controller to target a first plane of the 3D NAND die, starting to service the first command, receiving a second command from the controller to target a second plane of the 3D NAND die while the first plane is busy, and starting to service the second command independent of a status of the first plane. Any of the examples herein describing operation at a plane-level can also apply to a group-level. In one example, an apparatus includes a non-volatile memory die (e.g., a 3D NAND die) including multiple groups of memory cells. In one such example, the die includes multiple planes of memory cells, the multiple planes grouped into groups, each of the groups including two or more planes. In one such example, control logic is to generate commands in response to requests from a host, each of the commands to access one of the groups, queue the commands in separate queues for each of the groups based on a target group of each of the commands, issue the commands to their target groups independent of other groups' status, and track completion status of the commands independently for each group.

The technology discussed herein may be provided in various computing systems (e.g., including a non-mobile computing device such as a desktop, workstation, server, rack system, etc., a mobile computing device such as a smartphone, tablet, Ultra-Mobile Personal Computer (UMPC), laptop computer, ULTRABOOK computing device, smart watch, smart glasses, smart bracelet, etc., and/or a client/edge device such as an Internet-of-Things (IoT) device (e.g., a sensor, a camera, etc.)).

### ADDITIONAL NOTES AND EXAMPLES

Example 1 includes an apparatus, comprising an array of linear cell channels, and a string of NAND memory cells arranged along a cell channel of the array of linear cell channels, wherein the cell channel comprises less than E17 halogen atoms per cubic centimeter, and wherein an AWGHM of the polysilicon cell channel, when generated without pre-DA and seeding, may be greater than 28 nanometers for a cell channel thickness of 20 nanometers and greater than 29 nanometers for a cell channel thickness of 16 nanometers (e.g., greater than 47 nanometers for a cell channel thickness of 20 nanometers and greater than 43 nanometers for a cell channel thickness of 16 nanometers in some examples; greater than 61 nanometers for a cell channel thickness of 20 nanometers, greater than 52 nanometers for a cell channel thickness of 15 nanometers, and greater than 10 nanometers for a cell channel thickness of 6 nanometers in some examples). Example 1 also includes an apparatus, comprising an array of linear cell channels, and a string of NAND memory cells arranged along a cell channel of the array of linear cell channels, wherein the cell channel comprises less than E17 halogen atoms per cubic centimeter, and wherein an area-weighted grain height mean (AWGHM) of the polysilicon cell channel, when generated with pre-DA and seeding, may be greater than 51 nanometers for a cell channel thickness of 20 nanometers, greater than 31 nanometers for a cell channel thickness of 16 nanometers, and greater than 6 nm for a cell channel thickness of 7 nanometers (e.g., greater than 58 nanometers for a cell channel thickness of 20 nanometers, greater than 47 nanometers for a cell channel thickness of 17 nanometers, and greater than 16 nanometers for a cell channel thickness of 7 nanometers in some examples; greater than 69 nanometers for a cell channel thickness of 20 nanometers, greater than 58 nanometers for a cell channel thickness of 17 nanometers, and greater than 27 nanometers for a cell channel thickness of 7 nanometers in some examples).

Example 2 includes the apparatus of Example 1, wherein the polysilicon cell channel layer comprises less than E16 halogen atoms per cubic centimeter.

Example 3 includes the apparatus of Example 1, wherein the polysilicon cell channel layer is substantially halogen-free.

Example 4 includes the apparatus of any of Examples 1 to 3, further comprising a tunnel oxide, wherein the polysilicon cell channel material is substantially chlorine-free at an interface between the polysilicon cell channel layer and the tunnel oxide layer.

Example 5 includes a memory device, comprising a controller, and NAND memory coupled to the controller, the NAND memory comprising an array of vertical NAND strings, wherein a vertical cell channel of the array includes a plurality of NAND cells arranged along the vertical cell channel with a tunnel oxide material disposed between the plurality of NAND cells and a polysilicon vertical cell channel, and wherein the polysilicon vertical cell channel comprises less than E17 halogen atoms per cubic centimeter, and wherein an area-weighted grain height mean (AWGHM) of the polysilicon vertical cell channel, when generated without pre-DA and seeding, may be greater than 28 nanometers for a cell channel thickness of 20 nanometers and greater than 29 nanometers for a cell channel thickness of 16 nanometers (e.g., greater than 47 nanometers for a cell channel thickness of 20 nanometers and greater than 43 nanometers for a cell channel thickness of 16 nanometers in some examples; greater than 61 nanometers for a cell channel thickness of 20 nanometers, greater than 52 nanometers for a cell channel thickness of 15 nanometers, and greater than 10 nanometers for a cell channel thickness of 6 nanometers in some examples). Example 5 also includes a memory device, comprising a controller, and NAND memory coupled to the controller, the NAND memory comprising an array of vertical NAND strings, wherein a vertical cell channel of the array includes a plurality of NAND cells arranged along the vertical cell channel with a tunnel oxide material disposed between the plurality of NAND cells and a polysilicon vertical cell channel, and wherein the polysilicon vertical cell channel comprises less than E17 halogen atoms per cubic centimeter, and wherein an area-weighted grain height mean (AWGHM) of the polysilicon vertical cell channel, when generated with pre-DA and seeding, may be greater than 51 nanometers for a cell channel thickness of 20 nanometers, greater than 31 nanometers for a cell channel thickness of 16 nanometers, and greater than 6 nm for a cell channel thickness of 7 nanometers (e.g., greater than 58 nanometers for a cell channel thickness of 20 nanometers, greater than 47 nanometers for a cell channel thickness of 17 nanometers, and greater than 16 nanometers for a cell channel thickness of 7 nanometers in some examples; greater than 69 nanometers for a cell channel thickness of 20 nanometers, greater than 58 nanometers for a cell channel thickness of 17 nanometers, and greater than 27 nanometers for a cell channel thickness of 7 nanometers in some examples).

Example 6 includes the memory device of Example 5, wherein the polysilicon vertical cell channel comprises less than E16 halogen atoms per cubic centimeter.

Example 7 includes the memory device of Example 5, wherein the polysilicon vertical cell channel is substantially halogen-free.

Example 8 includes the memory device of any of Examples 5-7, wherein the halogen comprises chlorine and wherein the polysilicon vertical cell channel is substantially chlorine-free at an interface between the polysilicon vertical cell channel and the tunnel oxide layer.

Example 9 includes the memory device of any of Examples 5 to 8, wherein the NAND memory comprises three-dimensional NAND memory.

Example 10 includes a system, comprising a processor, and a three-dimensional (3D) NAND memory device coupled to the processor, the 3D NAND memory device comprising 3D NAND media comprising an array of vertical NAND strings, wherein a vertical cell channel of the array includes a plurality of NAND cells arranged along the vertical cell channel with a dielectric material disposed between the plurality of NAND cells and a polysilicon vertical cell channel, and wherein the polysilicon vertical cell channel comprises less than E17 halogen atoms per cubic centimeter, and wherein an area-weighted grain height mean (AWGHM) of the polysilicon vertical cell channel, when generated without pre-DA and seeding, may be greater than 28 nanometers for a cell channel thickness of 20 nanometers and greater than 29 nanometers for a cell channel thickness of 16 nanometers (e.g., greater than 47 nanometers for a cell channel thickness of 20 nanometers and greater than 43 nanometers for a cell channel thickness of 16 nanometers in some examples; greater than 61 nanometers for a cell channel thickness of 20 nanometers, greater than 52 nanometers for a cell channel thickness of 15 nanometers, and greater than 10 nanometers for a cell channel thickness of 6 nanometers in some examples). Example 10 also includes a system, comprising a processor, and a three-dimensional (3D) NAND memory device coupled to the processor, the 3D NAND memory device comprising 3D NAND media comprising an array of vertical NAND strings, wherein a vertical cell channel of the array includes a plurality of NAND cells arranged along the vertical cell channel with a dielectric material disposed between the plurality of NAND cells and a polysilicon vertical cell channel, and wherein the polysilicon vertical cell channel comprises less than E17 halogen atoms per cubic centimeter, and wherein an area-weighted grain height mean (AWGHM) of the polysilicon vertical cell channel, when generated with pre-DA and seeding, may be greater than 51 nanometers for a cell channel thickness of 20 nanometers, greater than 31 nanometers for a cell channel thickness of 16 nanometers, and greater than 6 nm for a cell channel thickness of 7 nanometers (e.g., greater than 58 nanometers for a cell channel thickness of 20 nanometers, greater than 47 nanometers for a cell channel thickness of 17 nanometers, and greater than 16 nanometers for a cell channel thickness of 7 nanometers in some examples; greater than 69 nanometers for a cell channel thickness of 20 nanometers, greater than 58 nanometers for a cell channel thickness of 17 nanometers, and greater than 27 nanometers for a cell channel thickness of 7 nanometers in some examples).

Example 11 includes the apparatus of Example 10, wherein the polysilicon vertical cell channel comprises less than E16 halogen atoms per cubic centimeter.

Example 12 includes the apparatus of Example 10, wherein the polysilicon vertical cell channel is substantially halogen-free.

Example 13 includes the apparatus of any of Examples 10 to 12, wherein the halogen comprises chlorine and wherein the polysilicon vertical cell channel is substantially chlorine-free at an interface between the polysilicon vertical cell channel and the dielectric material.

Example 14 includes the system of any of Examples 10 to 13, further comprising one or more of a display, a battery, and a peripheral device coupled to the processor.

Example 15 includes a method to manufacture a memory device, comprising forming a vertical sacrificial silicon liner through a plurality of vertically aligned NAND cells and over a tunnel oxide layer, completing an anisotropic dry etch (also known as a “punch etch”) to etch through the silicon liner and underlying layers and stop on the surface of the silicon source at the bottom of the pillar (leaving material on the pillar sidewall untouched), removing the sacrificial silicon liner with a solution selected to promote hydroxyl formation on the surface of the tunnel oxide layer, depositing a silicon layer with a main deposition precursor that includes a higher order silane with three or more silicon atoms on the tunnel oxide surface, and annealing the deposited layer of silicon material with a forming gas to yield a polysilicon cell channel (through crystallization of the aforementioned silicon material).

Example 16 includes the method of Example 15, wherein the solution is further selected to remove adventitious carbon.

Example 17 includes the method of any of Examples 15 to 16, wherein the main deposition precursor further includes a hydrogen of a terminal silicon of the higher order silane replaced with a dialkylamino group.

Example 18 includes the method of any of Examples 15 to 17, wherein the forming gas includes hydrogen.

Example 19 includes the method of any of Examples 15 to 18, further comprising, after removing the sacrificial silicon liner and before depositing silicon via main deposition precursor materials, annealing the tunnel oxide layer and subsequently depositing a silicon layer via seed deposition precursor materials on the tunnel oxide layer.

Example 20 includes the method of Example 19, wherein annealing the tunnel oxide layer further comprises dehydrating the surface of the tunnel oxide layer to optimize hydroxyl density on the tunnel oxide surface (for the subsequent seeding step).

Example 21 includes the method of any of Examples 19 to 20, wherein the seed precursor comprises a higher order silane with three or more silicon atoms.

Example 22 includes the method of Example 21, wherein the seed precursor further includes a hydrogen of a terminal silicon of the higher order silane replaced with a dialkylamino group.

Example 23 includes an apparatus, comprising means for forming a vertical sacrificial silicon liner through a plurality of vertically aligned NAND cells and over a tunnel oxide layer, means for completing an anisotropic dry etch (also known as a “punch etch”) to etch through the silicon liner and underlying layers and stop on the surface of the silicon source at the bottom of the pillar (leaving material on the pillar sidewall untouched), means for removing the sacrificial silicon liner with a solution selected to promote hydroxyl formation on the surface of the tunnel oxide layer, means for depositing a silicon layer with a main deposition precursor that includes a higher order silane with three or more silicon atoms on the tunnel oxide surface, and means for annealing the deposited layer of silicon material with a forming gas to yield a polysilicon cell channel (through crystallization of the aforementioned silicon material).

Example 24 includes the apparatus of Example 23, wherein the solution is further selected to remove adventitious carbon.

Example 25 includes the apparatus of any of Examples 23 to 24, wherein the main precursor further includes a hydrogen of a terminal silicon of the higher order silane replaced with a dialkylamino group.

Example 26 includes the apparatus of any of Examples 23 to 25, wherein the forming gas includes hydrogen.

Example 27 includes the apparatus of any of Examples 23 to 26, further comprising means for annealing the tunnel oxide layer and means for subsequently depositing a silicon layer via seed deposition precursor materials on the tunnel oxide layer.

Example 28 includes the apparatus of Example 27, wherein the means for annealing the tunnel oxide layer further comprises means for dehydrating the surface of the tunnel oxide layer to optimize hydroxyl density on the tunnel oxide surface (for the subsequent seeding step).

Example 29 includes the apparatus of any of Examples 28 to 27, wherein the seed precursor comprises a higher order silane with three or more silicon atoms.

Example 30 includes the apparatus of Example 29, wherein the seed precursor further includes a hydrogen of a terminal silicon of the higher order silane replaced with a dialkylamino group.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrase “one or more of A, B, and C” and the phrase “one or more of A, B, or C” both may mean A; B; C; A and B; A and C; B and C; or A, B and C. Various components of the systems described herein may be implemented in software, firmware, and/or hardware and/or any combination thereof. For example, various components of the systems or devices discussed herein may be provided, at least in part, by hardware of a computing SoC such as may be found in a computing system such as, for example, a smart phone. Those skilled in the art may recognize that systems described herein may include additional components that have not been depicted in the corresponding figures. For example, the systems discussed herein may include additional components such as bit stream multiplexer or de-multiplexer modules and the like that have not been depicted in the interest of clarity.

While implementation of the example processes discussed herein may include the undertaking of all operations shown in the order illustrated, the present disclosure is not limited in this regard and, in various examples, implementation of the example processes herein may include only a subset of the operations shown, operations performed in a different order than illustrated, or additional operations.

In addition, any one or more of the operations discussed herein may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more graphics processing unit(s) or processor core(s) may undertake one or more of the blocks of the example processes herein in response to program code and/or instructions or instruction sets conveyed to the processor by one or more machine-readable media. In general, a machine-readable medium may convey software in the form of program code and/or instructions or instruction sets that may cause any of the devices and/or systems described herein to implement at least portions of the operations discussed herein and/or any portions the devices, systems, or any module or component as discussed herein.

As used in any implementation described herein, the term “module” refers to any combination of software logic, firmware logic, hardware logic, and/or circuitry configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, fixed function circuitry, execution unit circuitry, and/or firmware that stores instructions executed by programmable circuitry. The modules may, collectively or individually, be embodied as circuitry that forms part of a larger system, for example, an integrated circuit (IC), system on-chip (SoC), and so forth.

Various examples may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one example may be implemented by representative instructions stored on a machine-readable medium that represents various logic within the processor, that when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, that are apparent to persons skilled in the art to which the present disclosure pertains are deemed to lie within the spirit and scope of the present disclosure.

It will be recognized that the examples are not limited to the examples so described, but may be practiced with modification and alteration without departing from the scope of the appended claims. For example, the above examples may include specific combination of features. However, the above examples are not limited in this regard and, in various implementations, the above examples may include the undertaking only a subset of such features, undertaking a different order of such features, undertaking a different combination of such features, and/or undertaking additional features than those features explicitly listed. The scope of the examples should, therefore, be determined with reference to the appended claims, along with the full scope of equivalents to which such claims are entitled.

What is claimed is:

1. An apparatus, comprising:
an array of linear cell channels; and
a string of NAND memory cells arranged along a cell channel of the array of linear cell channels, wherein a polysilicon cell channel layer comprises material with less than E17 halogen atoms per cubic centimeter, wherein a thickness of the polysilicon cell channel layer is less than or equal to 25 nanometers, and wherein an area-weighted grain height mean (AWGHM) of the polysilicon cell channel layer is greater than 30 nanometers.

2. The apparatus of claim 1, wherein the polysilicon cell channel layer comprises less than E16 halogen atoms per cubic centimeter.

3. The apparatus of claim 1, wherein the polysilicon cell channel layer is substantially halogen-free.

4. The apparatus of claim 1, wherein the AWGHM of the polysilicon cell channel layer is greater than 40 nanometers.

5. The apparatus of claim 1, wherein the AWGHM of the polysilicon cell channel layer is greater than 50 nanometers.

6. The apparatus of claim 1, wherein the AWGHM of the polysilicon cell channel layer is greater than 60 nanometers.

7. The apparatus of claim 1, further comprising:
a tunnel oxide layer adjacent to the polysilicon cell channel layer, wherein the polysilicon cell channel layer is substantially chlorine-free at an interface between the polysilicon cell channel layer and the tunnel oxide layer.

8. A memory device, comprising:
a controller; and
NAND memory coupled to the controller, the NAND memory comprising:
an array of vertical NAND strings, wherein a polysilicon vertical cell channel of the array includes a plurality of NAND cells arranged along the polysilicon vertical cell channel with a tunnel oxide layer disposed between the plurality of NAND cells and the polysilicon vertical cell channel, and wherein the polysilicon vertical cell channel comprises less than E17 halogen atoms per cubic centimeter, wherein a thickness of the polysilicon vertical cell channel is less than or equal to 25 nanometers, and wherein an area-weighted grain height mean (AWGHM) of the polysilicon vertical cell channel is greater than 30 nanometers.

9. The memory device of claim 8, wherein the polysilicon vertical cell channel comprises less than E16 halogen atoms per cubic centimeter.

10. The memory device of claim 8, wherein the polysilicon vertical cell channel is substantially halogen-free.

11. The memory device of claim 8, wherein the AWGHM of the polysilicon vertical cell channel is greater than 50 nanometers.

12. The memory device of claim 8, wherein the AWGHM at a middle portion of the polysilicon vertical cell channel is greater than 60 nanometers.

13. The memory device of claim 8, wherein the polysilicon vertical cell channel is substantially chlorine-free at an interface between the polysilicon vertical cell channel and the tunnel oxide layer.

14. The memory device of claim 8, wherein the NAND memory comprises three-dimensional NAND memory.

15. A system, comprising:
a processor; and
a three-dimensional (3D) NAND memory device coupled to the processor, the 3D NAND memory device comprising:
3D NAND media comprising an array of vertical NAND strings, wherein a polysilicon vertical cell channel of the array includes a plurality of NAND cells arranged along the polysilicon vertical cell channel with a dielectric material disposed between the plurality of NAND cells and the polysilicon vertical cell channel, and wherein the polysilicon vertical cell channel comprises less than E17 halogen atoms per cubic centimeter, wherein a thickness of the polysilicon vertical cell channel is less than or equal to 25 nanometers, and wherein an area-weighted grain height mean (AWGHM) of the polysilicon vertical cell channel is greater than 30 nanometers.

16. The system of claim 15, wherein the polysilicon vertical cell channel comprises less than E16 halogen atoms per cubic centimeter.

17. The system of claim 15, wherein the polysilicon vertical cell channel is substantially halogen-free.

18. The system of claim 15, wherein the AWGHM of the polysilicon vertical cell channel is greater than 45 nanometers.

19. The system of claim 15, wherein the AWGHM at a middle portion of the polysilicon vertical cell channel is greater than 60 nanometers.

20. The system of claim 15, wherein the polysilicon vertical cell channel is substantially chlorine-free at an interface between the polysilicon vertical cell channel and the dielectric material.
